(19) United States
(12) Patent Application Publication
(10) Pub. No.: US 2016/0315255 A1
(43) Pub. Date: Oct. 27, 2016

(54) RESISTIVE RANDOM ACCESS MEMORY

(71) Applicant: Winbond Electronics Corp., Taichung City (TW)

(72) Inventors: Frederick Chen, Taichung City (TW); Ping-Kun Wang, Taichung City (TW); Shao-Ching Liao, Taichung City (TW); Meng-Hung Lin, Taichung City (TW)

(21) Appl. No.: 15/067,184

(22) Filed: Mar. 11, 2016

(30) Foreign Application Priority Data
Apr. 27, 2015 (TW) 104113408

(51) Int. Cl. H01L 45/00

(52) U.S. Cl. CPC H01L 45/1266; H01L 45/085; H01L 45/1233; H01L 45/145

(57) ABSTRACT

A resistive random access memory (RRAM) including a first electrode, a second electrode, and a variable-resistance oxide layer disposed between the first electrode and the second electrode is provided. The RRAM further includes an oxygen exchange layer, an oxygen-rich layer, and a first oxygen barrier layer. The oxygen exchange layer is disposed between the variable-resistance oxide layer and the second electrode. The oxygen-rich layer is disposed between the oxygen exchange layer and the second electrode. The first oxygen barrier layer is disposed between the oxygen exchange layer and the oxygen-rich layer.

### CROSS-REFERENCE TO RELATED APPLICATION

This application claims the priority benefit of Taiwan application serial no. 104113408, filed on Apr. 27, 2015. The entirety of the above-mentioned patent application is hereby incorporated by reference herein and made a part of this specification.

### BACKGROUND OF THE INVENTION

1. Field of the Invention

The invention relates to a non-volatile memory, and more particularly, to a resistive random access memory.

2. Description of Related Art

Currently, one non-volatile memory device actively developed by industries is a resistive random access memory (RRAM), and the RRAM has advantages such as low write-in operation voltage, short write time and erase time, long memorizing time, non-destructive read out, multi-state memory, simple structure, and small required area. As a result, the RRAM has the potential to become one of the widely-adopted non-volatile memory devices in personal computers and electronic equipments in the future.

The RRAM is generally formed by an top electrode, a bottom electrode, and a variable-resistance oxide layer between the top electrode and the bottom electrode. Since an electrically conductive path inside the RRAM controls a low-resistance state (LRS) via oxygen vacancy, oxygen ion diffusion susceptible to temperature is the key factor in controlling the thermal stability of the RRAM. Specifically, it's hard to keep the RRAM in the low-resistance state at high temperature, thus causing the capability of high-temperature data retention (HTDR) being degraded.

It is known that an oxygen-rich layer such as titanium oxynitride (TiON) can be used to prevent the diffusion of current, so as to increase current density, and thereby increase HTDR.

However, once the oxygen-rich layer (such as titanium oxynitride) loses oxygen ions, the oxygen-rich layer loses the above-mentioned function such that it cannot effectively increase the HTDR of the RRAM.

### SUMMARY OF THE INVENTION

The invention provides a resistive random access memory (RRAM) capable of effectively preventing an oxygen-rich layer from losing oxygen ions, such that high-temperature data retention (HTDR) of the RRAM can be increased.

The invention provides an RRAM including a first electrode, a second electrode, and a variable-resistance oxide layer disposed between the first electrode and the second electrode. The RRAM further includes an oxygen exchange layer, an oxygen-rich layer, and a first oxygen barrier layer. The oxygen exchange layer is disposed between the variable-resistance oxide layer and the second electrode. The oxygen-rich layer is disposed between the oxygen exchange layer and the second electrode. The first oxygen barrier layer is disposed between the oxygen exchange layer and the oxygen-rich layer.

According to an embodiment of the invention, in the RRAM, the first electrode is, for instance, a titanium-rich layer.

According to an embodiment of the invention, in the RRAM, the oxygen affinity of the oxygen exchange layer is, for instance, greater than the oxygen affinity of the first electrode.

According to an embodiment of the invention, in the RRAM, the material of the second electrode is, for instance, titanium nitride (TiN), tantalum nitride (TaN), titanium (Ti), or tantalum (Ta).

According to an embodiment of the invention, in the RRAM, the material of the variable-resistance oxide layer is, for instance, a transition metal oxide (TMO).

According to an embodiment of the invention, in the RRAM, the material of the oxygen exchange layer is, for instance, titanium, tantalum, hafnium (Hf), zirconium (Zr), platinum (Pt), or aluminum (Al).

According to an embodiment of the invention, in the RRAM, the material of the oxygen-rich layer is, for instance, titanium oxynitride or tantalum oxynitride (TaON).

According to an embodiment of the invention, in the RRAM, the material of the first oxygen barrier layer is, for instance, titanium nitride or tantalum nitride.

According to an embodiment of the invention, the RRAM further includes a second oxygen barrier layer disposed between the oxygen-rich layer and the second electrode.

According to an embodiment of the invention, in the RRAM, the material of the second oxygen barrier layer is, for instance, titanium nitride or tantalum nitride.

Based on the above, in the RRAM provided in the invention, since the first oxygen barrier layer is disposed between the oxygen exchange layer and the oxygen-rich layer, the first oxygen barrier layer can prevent oxygen ions in the oxygen-rich layer from entering the oxygen exchange layer, and can effectively prevent the oxygen-rich layer from losing oxygen ions. Therefore, by disposing the first oxygen barrier layer, the oxygen-rich layer of the RRAM of the present invention can retain the functions of preventing current spreading and increasing current density, thus increasing the HTDR of the RRAM.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional schematic of a resistive random access memory of an embodiment of the invention.

FIG. 2 is a cross-sectional schematic of a resistive random access memory of another embodiment of the invention.

FIG. 3 is a cross-sectional schematic of a resistive random access memory of another embodiment of the invention.

### DESCRIPTION OF THE EMBODIMENTS

Figures are provided in the present specification to more fully convey the concept of the invention, and embodiments of the invention are illustrated in the figures.

However, the invention can also adopt many different forms for implementation, and the invention should not be construed as limited to the following embodiments. In actuality, the provided embodiments are only intended to make the invention more thorough and complete, and to convey the scope of the invention to those having ordinary skill in the art.

In the figures, for clarity, the size and the relative size of each layer and each region may be exaggerated.

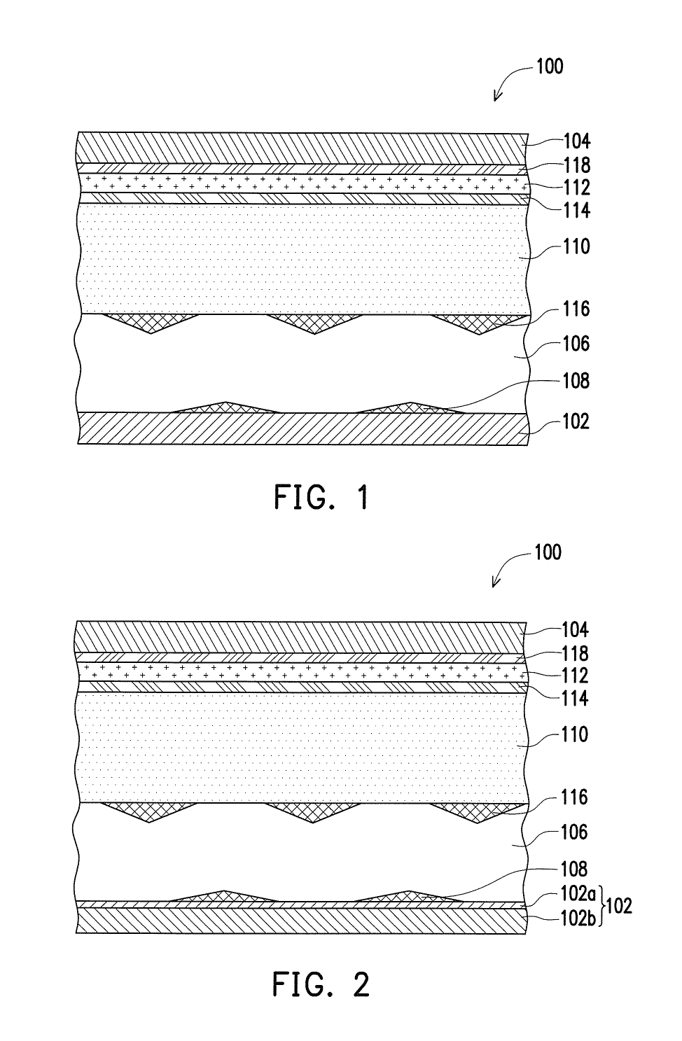

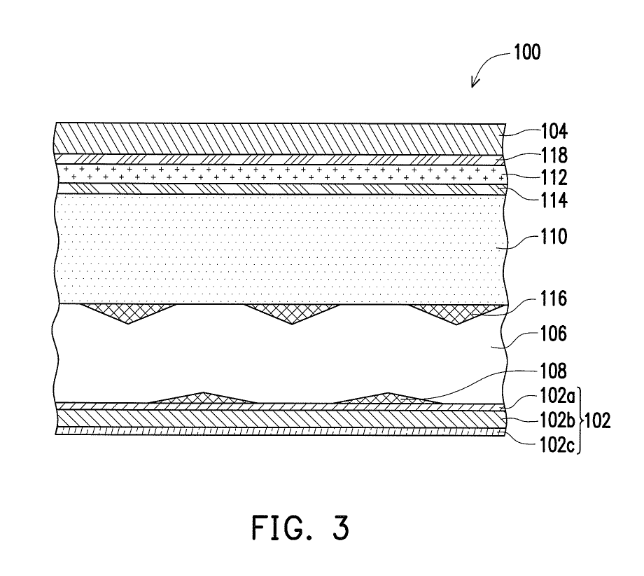

FIG. 1 is a cross-sectional schematic of a resistive random access memory (RRAM) of an embodiment of the invention. FIG. 2 is a cross-sectional schematic of an RRAM of another embodiment of the invention. FIG. 3 is a cross-sectional schematic of an RRAM of another embodiment of the invention.

Referring to FIG. 1 to FIG. 3 at the same time, an RRAM 100 includes a first electrode 102, a second electrode 104, and a variable-resistance oxide layer 106 disposed between the first electrode 102 and the second electrode 104.

The first electrode 102 can be used as a bottom electrode. In addition to a general conductive layer, the first electrode 102 can also be a titanium-rich layer. In the present embodiment, the first electrode 102 is exemplified as a titanium-rich layer. When the first electrode 102 is a titanium-rich layer, an oxygen vacancy patch 108 can be more readily generated at the interface of the first electrode 102 and the variable-resistance oxide layer 106, thus facilitating the formation of a conductive filament. Moreover, the first electrode 102 can be a single-layer structure or a multilayer structure.

In the embodiment of FIG. 1, the first electrode 102 is exemplified as a single-layer structure. The material of the first electrode 102 is, for instance, titanium nitride, such as TiNx (x<1), which can be achieved by reducing nitrogen flow during the sputtering process of titanium nitride.

In the embodiments of FIG. 2 and FIG. 3, the first electrode 102 is exemplified as a multilayer structure. Referring to FIG. 2, the first electrode 102 includes a titanium nitride layer 102a and a titanium layer 102b disposed by stacking, wherein the titanium nitride layer 102a and the variable-resistance oxide layer 106 can be in contact with each other. In a thermal process, nitrogen in the titanium nitride layer 102a will move to the titanium layer 102b, such that the titanium nitride layer 102a can be in a titanium-rich state. Moreover, the degree of titanium-richness of the first electrode 102 can be adjusted via the thickness of each of the titanium nitride layer 102a and the titanium layer 102b. Moreover, as shown in FIG. 3, the first electrode 102 can also include the titanium nitride layer 102a, the titanium nitride layer 102c, and the titanium layer 102b located between the titanium nitride layer 102a and the titanium nitride layer 102c, such that the first electrode 102 can be a titanium-rich layer. The forming method of the titanium nitride layer 102a, the titanium layer 102b, and the titanium nitride layer 102c is, for instance, a physical vapor deposition (PVD) method.

The second electrode 104 can be used as a top electrode. The material of the second electrode 104 is, for instance, titanium nitride, tantalum nitride, titanium, or tantalum. The forming method of the second electrode 104 is, for instance, a PVD method or an atomic layer deposition (ALD) method.

Referring further to FIG. 1 to FIG. 3, the material of the variable-resistance oxide layer 106 is, for instance, a transition metal oxide such as hafnium oxide or other suitable metal oxides. The forming method of the variable-resistance oxide layer 106 is, for instance, a PVD method or an ALD method.

The RRAM 100 further includes an oxygen exchange layer 110, an oxygen-rich layer 112, and a first oxygen barrier layer 114.

The oxygen exchange layer 110 is disposed between the variable-resistance oxide layer 106 and the second electrode 104, and an oxygen vacancy patch 116 can be generated at the interface of the oxygen exchange layer 110 and the variable-resistance oxide layer 106, thus facilitating the forming of a conductive filament. The oxygen affinity of the oxygen exchange layer 110 is, for instance, greater than the oxygen affinity of the first electrode 102, such that the oxygen vacancy patch 116 and the oxygen vacancy patch 108 are not symmetric to each other, and therefore the occurrence of complementary switching (CS) can be reduced. The material of the oxygen exchange layer 110 is, for instance, titanium, tantalum, hafnium, zirconium, platinum, or aluminum. The forming method of the oxygen exchange layer 110 is, for instance, a PVD method or an ALD method.

The oxygen-rich layer 112 is disposed between the oxygen exchange layer 110 and the second electrode 104. The oxygen-rich layer 112 can prevent current spreading, so as to increase current density, and thereby increase the capability of high-temperature data retention (HTDR). The material of the oxygen-rich layer 112 is, for instance, titanium oxynitride or tantalum oxynitride. The forming method of the oxygen-rich layer 112 is, for instance, a PVD method or an ALD method. The resistance value of the oxygen-rich layer 112 is, for instance, 500 ohm to 5 Kohm, such as 1 Kohm. The sheet resistance value of the oxygen-rich layer 112 is, for instance, greater than 1 Kohm/sq.

The first oxygen barrier layer 114 is disposed between the oxygen exchange layer 110 and the oxygen-rich layer 112. The first oxygen barrier layer 114 can block oxygen ions in the oxygen-rich layer 112 from moving to the outside of the oxygen-rich layer 112, and therefore the first oxygen barrier layer 114 can block oxygen ions in the oxygen-rich layer 112 from entering the oxygen exchange layer 110, such that loss of oxygen ions of the oxygen-rich layer 112 can be effectively prevented. As a result, the oxygen-rich layer 112 can retain the functions of preventing current spreading and increasing current density, thus increasing the HTDR of the RRAM 100. The material of the oxygen-barrier layer 114 is, for instance, titanium nitride or tantalum nitride. The forming method of the first oxygen barrier layer 114 is, for instance, a PVD method or an ALD method.

Moreover, the RRAM 100 can further optionally include a second oxygen barrier layer 118. The second oxygen barrier layer 118 is disposed between the oxygen-rich layer 112 and the second electrode 104. The second oxygen barrier layer 118 can further prevent the oxygen-rich layer 112 from losing oxygen ions during high-temperature dissociation. As a result, the oxygen-rich layer 118 can retain the functions of preventing current spreading and increasing current density, thus increasing the HTDR of the RRAM 100. The material of the oxygen-barrier layer 118 is, for instance, titanium nitride or tantalum nitride. The forming method of the second oxygen barrier layer 118 is, for instance, a PVD method or an ALD method. In other embodiments, when the material of the second electrode 104 is an oxygen barrier material (such as titanium nitride or tantalum nitride), the second oxygen barrier layer 118 can also not be disposed between the oxygen-rich layer 112 and the second electrode 104.

It can be known from the above embodiments that, since the first oxygen barrier layer 114 is disposed between the oxygen exchange layer 110 and the oxygen-rich layer 112, the first oxygen barrier layer 114 can prevent oxygen ions in the oxygen-rich layer 112 from entering the oxygen exchange layer 110, and can effectively prevent the oxygen-rich layer 112 from losing oxygen ions. Therefore, by disposing the first oxygen barrier layer 114, the oxygen-rich layer 112 of the RRAM 100 of the present invention can retain the functions of preventing current spreading and increasing current density, thus increasing the HTDR of the RRAM 100.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A resistive random access memory, comprising a first electrode, a second electrode, and a variable-resistance oxide layer disposed between the first electrode and the second electrode, the resistive random access memory further comprising:
an oxygen exchange layer disposed between the variable-resistance oxide layer and the second electrode;
an oxygen-rich layer disposed between the oxygen exchange layer and the second electrode; and
a first oxygen barrier layer disposed between the oxygen exchange layer and the oxygen-rich layer.

2. The resistive random access memory of claim 1, wherein the first electrode comprises a titanium-rich layer.

3. The resistive random access memory of claim 1, wherein an oxygen affinity of the oxygen exchange layer is greater than an oxygen affinity of the first electrode.

4. The resistive random access memory of claim 1, wherein a material of the second electrode comprises titanium nitride, tantalum nitride, titanium, or tantalum.

5. The resistive random access memory of claim 1, wherein a material of the variable-resistance oxide layer comprises transition metal oxide.

6. The resistive random access memory of claim 1, wherein a material of the oxygen exchange layer comprises titanium, tantalum, hafnium, zirconium, platinum, or aluminum.

7. The resistive random access memory of claim 1, wherein a material of the oxygen-rich layer comprises titanium oxynitride or tantalum oxynitride.

8. The resistive random access memory of claim 1, wherein a material of the first oxygen barrier layer comprises titanium nitride or tantalum nitride.

9. The resistive random access memory of claim 1, further comprising a second oxygen barrier layer disposed between the oxygen-rich layer and the second electrode.

10. The resistive random access memory of claim 9, wherein a material of the second oxygen barrier layer comprises titanium nitride or tantalum nitride.
